(19) United States
(12) Patent Application Publication
(10) Pub. No.: US 2015/0173181 A1
(43) Pub. Date: Jun. 18, 2015

(54) Enlarged Press-Fit Hole

(71) Applicant: Cisco Technology, Inc., San Jose, CA (US)

(72) Inventors: Dewen Xu, Shanghai (CN); Jingping Wang, Shanghai (CN); Jianqun Fu, Shanghai (CN); Jiang Wang, Shanghai (CN); Jing An, Shanghai (CN)

(73) Assignee: Cisco Technology, Inc., San Jose, CA (US)

(21) Appl. No.: 14/107,069

(22) Filed: Dec. 16, 2013

(51) Int. Cl. H05K 1/02; H05K 3/00

(52) U.S. Cl. CPC H05K 1/0284; H05K 3/00

(57) ABSTRACT

An apparatus may be provided. The apparatus may comprise a circuit board and a bore. The circuit board may have a component side surface and a bottom side surface. The bore may be disposed in the circuit board. The bore may extent from the component side surface to the bottom side surface. The bore may comprise a first portion and a second portion. The first portion may have a first diameter. The second portion may be disposed between the first portion and the component side surface. The second portion may have a second diameter greater than the first diameter.

### TECHNICAL FIELD

The present disclosure relates generally to electrical connectors.

### BACKGROUND

An electrical connector is an electro-mechanical device for joining electrical circuits as an interface using a mechanical assembly. The connection may be temporary, as for portable equipment, require a tool for assembly and removal, or serve as a permanent electrical joint between two wires or devices.

There are many types of electrical connectors. Connectors may join two lengths of flexible copper wire or cable, or connect a wire or cable or optical interface to an electrical terminal. In computing, an electrical connector may also be known as a physical interface. Cable glands, known as cable connectors, connect wires to devices mechanically rather than electrically and are distinct from quick-disconnects performing the latter.

### BRIEF DESCRIPTION OF THE DRAWINGS

The accompanying drawings, which are incorporated in and constitute a part of this disclosure, illustrate various embodiments of the present disclosure. In the drawings:

FIG. 1 shows a circuit board having a plurality of bores;

FIG. 2 shows a bore;

FIG. 3 shows a press-fit pin in a bore; and

FIG. 4 is a flow chart setting forth the general stages involved in a method for avoiding bent pins.

### DETAILED DESCRIPTION

### Overview

An apparatus may be provided. The apparatus may comprise a circuit board and a bore. The circuit board may have a component side surface and a bottom side surface. The bore may be disposed in the circuit board. The bore may extent from the component side surface to the bottom side surface. The bore may comprise a first portion and a second portion. The first portion may have a first diameter. The second portion may be disposed between the first portion and the component side surface. The second portion may have a second diameter greater than the first diameter.

Both the foregoing overview and the following example embodiment are examples and explanatory only, and should not be considered to restrict the disclosure's scope, as described and claimed. Further, features and/or variations may be provided in addition to those set forth herein. For example, embodiments of the disclosure may be directed to various feature combinations and sub-combinations described in the example embodiment.

### Example Embodiments

The following detailed description refers to the accompanying drawings. Wherever possible, the same reference numbers are used in the drawings and the following description to refer to the same or similar elements. While embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims.

Circuit components may be connected through a circuit board. These components may comprise, but are not limited to, integrated connectors that may be used to interface a device to the world outside the device. Various types of connections may be used to connect the circuit components to the circuit board. One type of connection may comprise a “press-fit” connection.

A press-fit connection may be made through the pressing in of a press-fit pin into a circuit board through a hole in the circuit board. The cross section diameter of the press-fit pin may be greater than a diameter of the circuit board hole. The difference between the press-fit cross section diameter and the circuit board hole diameter may result in a deformation of either the circuit board hole, the press-fit pin, or both during the insertion process of the press-fit pin into the circuit board hole. This deformation tends to create a snug electrical connection between the press-fit pin and the circuit board.

During the process of pressing the press-fit pin into the circuit board, the press-fit pin and the circuit board hole may not be lined up. In this case, the press-fit pin may be forced onto an edge of the circuit board hole or a component side surface of the circuit board. Consequently, the press-fit pin may not end up in the circuit board hole. Rather the press-fit pin may be bent or otherwise damaged through the pressing process. This may result in costly repairs to the circuit board and to the circuit component being connected to the circuit board.

Consistent with embodiments of the disclosure, bent press-fit pins may be avoided. To avoid bent press-fit pins, the circuit board hole into which the press-fit pin is to be inserted may be enlarged on the component side surface of the circuit board. The enlargement may help the alignment between the press-fit pin and the circuit board hole. In addition, the enlargement may help guide the press-fit pin into the circuit board hole during the press-fit process.

One way to enlarge the circuit board hole is by a “back-drill” process. Back-drill may be used to reduce the hole stub to improve the signal integrity by back drilling the circuit board hole on a bottom side surface of the circuit board. Consistent with embodiments of the disclosure, the circuit board hole may be back drilled for a length of the circuit board hole on the component side surface of the circuit board. Consequently, on the component side surface, the circuit board hole's diameter may be a little larger, but the rest of the circuit board hole's diameter may not be affected. Accordingly, the circuit board hole may still provide enough normal force to hold the press-fit pin.

By enlarging the circuit board hole on the component side surface of the circuit board, the bent press-fit pin issue in the press-fit process may be avoided. The diameter of the circuit board hole on the component side surface may be bigger than the bottom side. This may help the press-fit pin alignment and avoid the bent pin issue during the press-fit process. The diameter of the circuit board hole on the bottom side surface of the circuit board may provide enough normal force when the press-fit pins are in there respective circuit board holes.

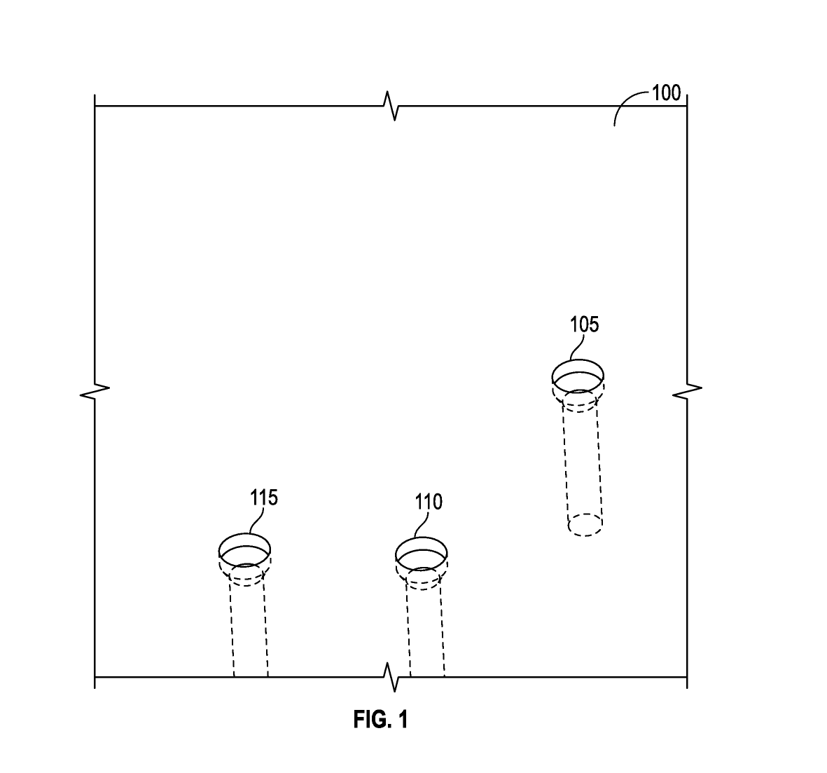

FIG. 1 shows a circuit board 100 having a plurality of bores. As shown in FIG. 1, the plurality of bores may comprise a first bore 105, a second bore 110, and a third bore 115. Circuit board 100 may comprise any number of bores and is not limited to three. As will be discussed in greater detail below, any one or more of the plurality of bores may respectively receive press-fit pins.

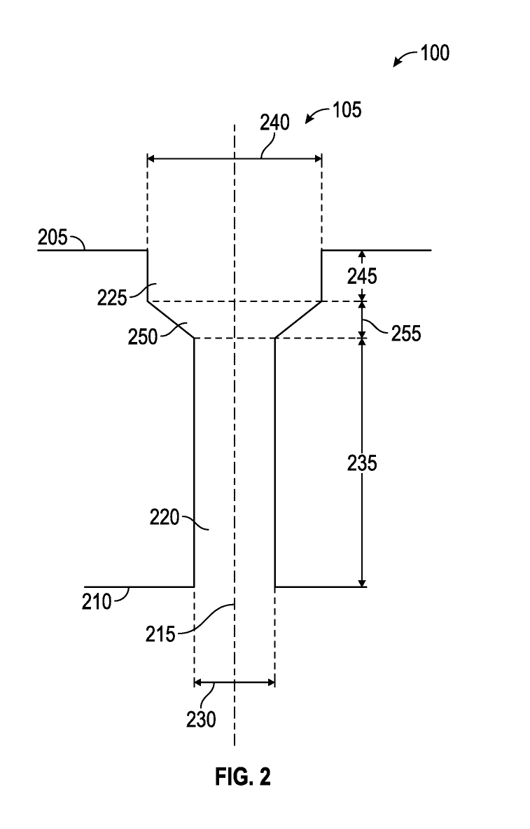

FIG. 2 shows first bore 105 in greater detail. As shown in FIG. 2, circuit board 100 may comprise a component side surface 205 and a bottom side surface 210. Component side surface 205 may comprise a surface onto which components are pressed onto circuit board 100. Circuit board 100 may have a thickness in a range from about 95 mils to about 105 mils. The thickness of circuit board 100 is not so limited and may comprise any thickness.

First bore 105 may have a bore axis 215, a first portion 220, and a second portion 225. First portion 220 may comprise a first diameter 230 and a first portion length 235. Bore axis 215 may be substantially perpendicular to component side surface 205. First portion 220 may have first portion length 235 in a range from about 82 mils to about 92 mils. First diameter 230 may range from about 16 mils to about 20 mils.

Second portion 225 may comprise a second diameter 240, a second portion length 245, a transitional section 250, and a transitional section length 255. Second diameter 240 may ranges from about 28 mils to about 32 mils. Second portion 225 may have second portion length 245 in a range from about 10 mils to about 16 mils. First portion 220 may be disposed between second portion 225 and bottom side surface 210. Second portion 225 may be disposed between first portion 220 and component side surface 205.

Transitional section 250 of second portion 225 may be adjacent first portion 220. Transitional section 250 may have transitional section length 225 in a range from about 2 mils to about 4 mils. Transitional section 250 may be straight, curved, or in any shape.

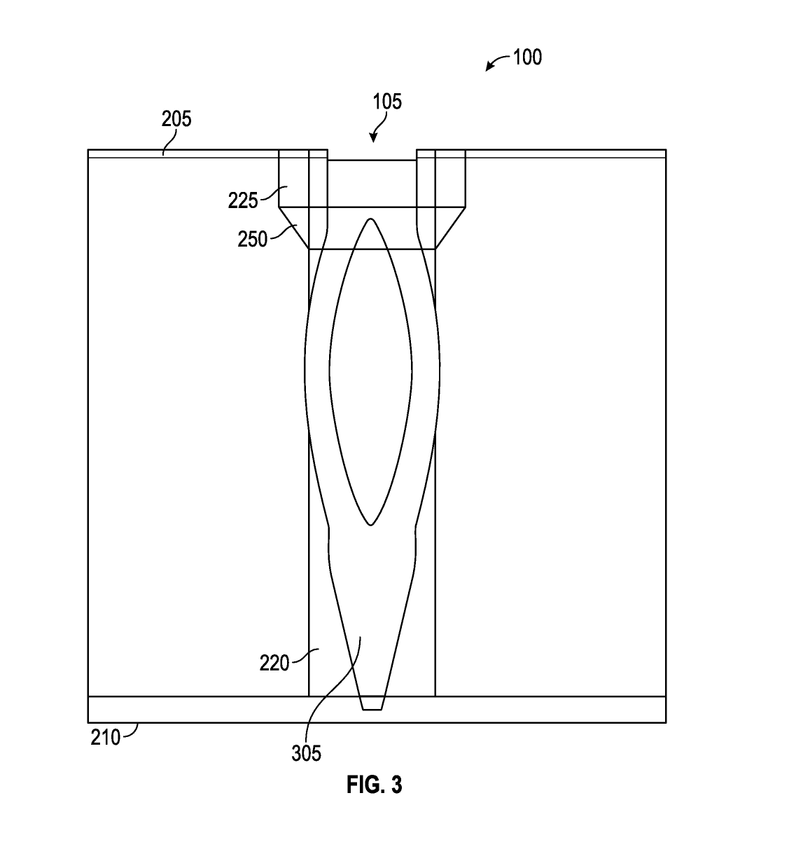

FIG. 3 shows a press-fit pin 305 in first bore 105. To avoid bent press-fit pins, the circuit board hole into which a press-fit pin is to be inserted may be enlarged. In other words first bore 105 may be provided with an enlargement (e.g. second portion 225) on component side surface 205 of circuit board 100. Second portion 225 may help the alignment between press-fit pin 305 and first bore 105. In addition, second portion 225 may help guide press-fit pin 305 into the circuit board hole during the press-fit process. For example, during the press-fit process, the alignment between press-fit pin 305 and first bore 105 may be enough for a tip of press-fit 305 to make it into second portion 225.

As press-fit pin 305 travels further into first bore 105, it may encounter transitional section 250 of second portion 225. Consequently, press-fit pin 305 may slide across transitional section 250 to guide press-fit pin 305 down into first potion 220. The difference between press-fit pin 305's diameter and first diameter 230 may result in a deformation of either first portion 220, press-fit pin 305, or both during the press-fit process of press-fit pin 305 into first bore 105. This deformation may create a snug electrical connection between press-fit pin 305 and an interior wall of first portion 220.

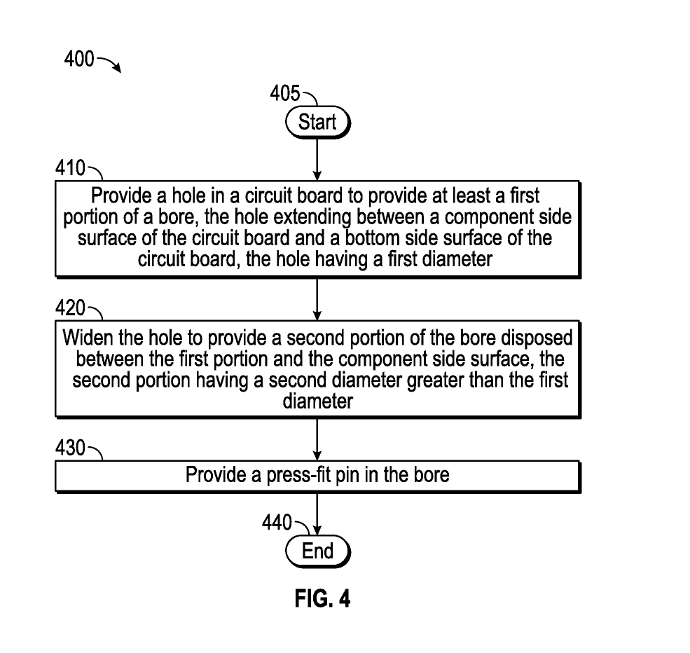

FIG. 4 is a flow chart setting forth the general stages involved in a method 400 consistent with an embodiment of the disclosure for avoiding bent pins. Ways to implement the stages of method 400 will be described in greater detail below.

Method 400 may begin at starting block 405 and proceed to stage 410 where a hole may be provided in circuit board 100 to provide at least first portion 220 of first bore 105. The hole may extend between component side surface 205 of circuit board 100 and bottom side surface 210 of circuit board 100. The hole may have a first diameter (e.g. first diameter 230.)

From stage 410, where the hole is provided in circuit board 100, method 400 may advance to stage 420 where the hole may be widened to provide second portion 225 of first bore 105 disposed between first portion 220 and component side surface 205. Second portion may have second diameter 240 that may be greater than first diameter 230. For example, one way to enlarge the hole may be to employ a back-drill process. Consistent with embodiments of the disclosure, the hole may be back drilled for a length (e.g. second portion length 245) of the hole on component side surface 205 of circuit board 100. Consequently, on component side surface 205, the hole's diameter (e.g. second diameter 240) may be a little larger, but the rest of the hole's diameter (e.g. first diameter 230) may not be affected. Accordingly, the hole may still provide enough normal force to hold, for example, press-fit pin 305.

Once the hole is widened in stage 420, method 400 may continue to stage 430 where press-fit pin 305 may be provided in first bore 105. For example, to avoid bent press-fit pins, the hole into which press-fit pin 305 is to be inserted may be enlarged. In other words first bore 105 may be provided with an enlargement (e.g. second portion 225) on component side surface 205 of circuit board 100. Second portion 225 may help the alignment between press-fit pin 305 and first bore 105. In addition, second portion 225 may help guide press-fit pin 305 into the circuit board hole during the press-fit process. For example, during the press-fit process, the alignment between press-fit pin 305 and first bore 105 may be enough for a tip of press-fit 305 to make it into second portion 225.

As press-fit pin 305 travels further into first bore 105, it may encounter transitional section 250 of second portion 225. Consequently, press-fit pin 305 may slide across transitional section 250 to guide press-fit pin 305 down into first potion 220. The difference between press-fit pin 305's diameter and first diameter 230 may result in a deformation of either first portion 220, press-fit pin 305, or both during the press-fit process of press-fit pin 305 into first bore 105. This deformation may create a snug electrical connection between press-fit pin 305 and an interior wall of first portion 220. Once press-fit pin 305 is provided in first bore in stage 430, method 400 may then end at stage 440.

An embodiment consistent with the disclosure may comprise an apparatus for avoiding bent pins. The apparatus may comprise a circuit board and a bore. The circuit board may have a component side surface and a bottom side surface. The bore may be disposed in the circuit board. The bore may extent from the component side surface to the bottom side surface. The bore may comprise a first portion and a second portion. The first portion may have a first diameter. The second portion may be disposed between the first portion and the component side surface. The second portion may have a second diameter greater than the first diameter.

Another embodiment consistent with the disclosure may comprise an apparatus for avoiding bent pins. The apparatus may comprise a bore disposed in a circuit board. The bore may extend from a component side surface of the circuit board to a bottom side surface of the circuit board. The bore may comprise a first portion and a second portion. The first portion may have a first diameter. The second portion may be disposed between the first portion and the component side surface. The second portion may have a second diameter greater than the first diameter. The second portion may have a transitional section adjacent the first portion.

Yet another embodiment consistent with the disclosure may comprise a method for avoiding bent pins. The method may comprise providing a hole in a circuit board to provide at least a first portion of a bore. The hole may extend between a component side surface of the circuit board and a bottom side surface of the circuit board. The hole having a first diameter. Next, the method may include widening the hole to provide a second portion of the bore disposed between the first portion and the component side surface. The second portion may have a second diameter greater than the first diameter. The method may include providing a press-fit pin in the bore.

Embodiments of the disclosure, for example, may be implemented as a computer process (method), a computing system, or as an article of manufacture, such as a computer program product or computer readable media. The computer program product may be a computer storage media readable by a computer system and encoding a computer program of instructions for executing a computer process. The computer program product may also be a propagated signal on a carrier readable by a computing system and encoding a computer program of instructions for executing a computer process. Accordingly, the present disclosure may be embodied in hardware and/or in software (including firmware, resident software, micro-code, etc.). In other words, embodiments of the present disclosure may take the form of a computer program product on a computer-usable or computer-readable storage medium having computer-usable or computer-readable program code embodied in the medium for use by or in connection with an instruction execution system. A computer-usable or computer-readable medium may be any medium that can contain, store, communicate, propagate, or transport the program for use by or in connection with the instruction execution system, apparatus, or device.

The computer-usable or computer-readable medium may be, for example but not limited to, an electronic, magnetic, optical, electromagnetic, infrared, or semiconductor system, apparatus, device, or propagation medium. More specific computer-readable medium examples (a non-exhaustive list), the computer-readable medium may include the following: an electrical connection having one or more wires, a portable computer diskette, a random access memory (RAM), a read-only memory (ROM), an erasable programmable read-only memory (EPROM or Flash memory), an optical fiber, and a portable compact disc read-only memory (CD-ROM). Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory.

Embodiments of the present disclosure, for example, are described above with reference to block diagrams and/or operational illustrations of methods, systems, and computer program products according to embodiments of the disclosure. The functions/acts noted in the blocks may occur out of the order as shown in any flowchart. For example, two blocks shown in succession may in fact be executed substantially concurrently or the blocks may sometimes be executed in the reverse order, depending upon the functionality/acts involved.

While certain embodiments of the disclosure have been described, other embodiments may exist. Furthermore, although embodiments of the present disclosure have been described as being associated with data stored in memory and other storage mediums, data can also be stored on or read from other types of computer-readable media, such as secondary storage devices, like hard disks, floppy disks, or a CD-ROM, a carrier wave from the Internet, or other forms of RAM or ROM. Moreover, the semantic data consistent with embodiments of the disclosure may be analyzed without being stored. In this case, in-line data mining techniques may be used as data traffic passes through, for example, a caching server or network router. Further, the disclosed methods' stages may be modified in any manner, including by reordering stages and/or inserting or deleting stages, without departing from the disclosure.

While the specification includes examples, the disclosure's scope is indicated by the following claims. Furthermore, while the specification has been described in language specific to structural features and/or methodological acts, the claims are not limited to the features or acts described above. Rather, the specific features and acts described above are disclosed as example for embodiments of the disclosure.

What is claimed is:

1. An apparatus comprising:
a circuit board having a component side surface and a bottom side surface; and
a bore disposed in the circuit board, the bore extending from the component side surface to the bottom side surface, the bore comprising:
a first portion having a first diameter, and
a second portion disposed between the first portion and the component side surface, the second portion having a second diameter greater than the first diameter.

2. The apparatus of claim 1, wherein the circuit board has a thickness in a range from about 95 mils to about 105 mils.

3. The apparatus of claim 1, wherein the first diameter ranges from about 16 mils to about 20 mils.

4. The apparatus of claim 1, wherein the second diameter ranges from about 28 mils to about 32 mils.

5. The apparatus of claim 1, wherein the first portion has a length in a range from about 82 mils to about 92 mils.

6. The apparatus of claim 1, wherein the second portion has a length in a range from about 10 mils to about 16 mils.

7. The apparatus of claim 1, wherein the first portion is disposed between the bottom surface and the second portion.

8. The apparatus of claim 1, wherein the second portion has a transitional section adjacent the first portion.

9. The apparatus of claim 8, wherein the transitional section has a length in a range from about 2 mils to about 4 mils.

10. The apparatus of claim 8, wherein the transitional section is curved.

11. The apparatus of claim 8, wherein the transitional section is straight.

12. The apparatus of claim 1, wherein the bore is substantially perpendicular to the component side surface.

13. The apparatus of claim 1, wherein a press-fit pin is disposed in the bore.

14. An apparatus comprising:
a bore disposed in a circuit board, the bore extending from a component side surface of the circuit board to a bottom side surface of the circuit board, the bore comprising:
a first portion having a first diameter, and
a second portion disposed between the first portion and the component side surface, the second portion having a second diameter greater than the first diameter, the second portion having a transitional section adjacent the first portion.

15. The apparatus of claim 14, wherein the first portion is disposed between the bottom surface and the transitional section.

16. The apparatus of claim 14, wherein the transitional section is curved.

17. The apparatus of claim 14, wherein the transitional section is straight.

18. The apparatus of claim 14, wherein the bore is substantially perpendicular to the component side surface.

19. The apparatus of claim 14, wherein a press-fit pin is disposed in the bore.

20. A method comprising:
providing a hole in a circuit board to provide at least a first portion of a bore, the hole extending between a component side surface of the circuit board and a bottom side surface of the circuit board, the hole having a first diameter;
widening the hole to provide a second portion of the bore disposed between the first portion and the component side surface, the second portion having a second diameter greater than the first diameter; and
providing a press-fit pin in the bore.

21. The method of claim 20, wherein providing the hole in the circuit board comprises providing the hole wherein the hole is substantially perpendicular to the component side surface.

22. The method of claim 20, wherein widening the hole further comprises providing a transitional section adjacent the first portion.

23. The method of claim 20, wherein widening the hole further comprises providing a transitional section adjacent the first portion, the transitional section being curved.

24. The method of claim 20, wherein widening the hole further comprises providing a transitional section adjacent the first portion, the transitional section being straight.

25. The method of claim 20, wherein widening the hole comprises using a back-drill process.
